(19) United States
(12) Patent Application Publication
(10) Pub. No.: US 2005/0122827 A1
(43) Pub. Date: Jun. 9, 2005

(54) Active matrix display and driving method therefor

(75) Inventor: Chun-Fu Wang, Taiwan (TW)

Correspondence Address: SILICON VALLEY PATENT GROUP LLP, 2350 MISSION COLLEGE BOULEVARD, SUITE 360, SANTA CLARA, CA, 95054, US

(73) Assignee: Hannstar Display Corp., Taipei (TW)

(21) Appl. No.: 10/923,200

(22) Filed: Aug. 20, 2004

(30) Foreign Application Priority Data
Dec. 4, 2003 (TW) 092134261

(51) Int. Cl. G11C 8/00

(52) U.S. Cl. 365/232

(57) ABSTRACT

This invention provides an active matrix display and a relevant driving method. The active matrix display includes a gate line driving circuit for generating a multiplexer controlling signal and plural gate line driving signals, a multiplexer, and a source line driving circuit having plural source line outputs in a horizontal direction. The multiplexer has a plurality of gate line outputs in a vertical direction and is electrically connected between the gate line driving circuit and the transistors of the display, wherein the gate line outputs are connected to the gate electrodes of the transistors, and the multiplexer is controlled by the multiplexer controlling signal and drives the gate line outputs in response to the gate line driving signals.

### FIELD OF THE INVENTION

This invention relates to a display and the driving method therefor, and more particular to an active matrix display and the driving method therefor.

### BACKGROUND OF THE INVENTION

The active matrix display is the display having a transistor circuit as its optical switch. The most common type of active matrix display is the thin film transistor-liquid crystal display (TFT-LCD). Please refer to FIG. 1, which is a schematic view of the active matrix display in the prior art. Generally, an active matrix display includes four parts as follows: the pixel electrode 11 transforming electrical signals to optical images by the optoelectronic materials inside, an switch element 12, usually a transistor is used as an active switch element, a plurality of vertical signal lines 13, which are also called as data lines or source lines, transmitting image signals to display, and a plurality of horizontal gate lines 14, which are also called as scanning lines, transmitting the switching signals of the switch element 12. Since the components of the active matrix display are arranged in matrix, it is necessary to use both horizontal and vertical driving circuits to transmit the image (data voltage) signals and the switching (scanning) signals to the display.

Please refer to FIG. 2 and FIG. 3, which respectively illustrate a schematic view and a timing chart of a conventional gate driving circuit of the display. As shown in FIG. 2, a gate line driving circuit 21 includes a gate line controlling circuit 211, a plurality of level shifters 212 and a plurality of gate lines 22. And each horizontal gate line 22 needs a level shifter 212 as the driving element in the conventional gate line driving circuit 21. To comply with the raised display resolution, the number of the level shifter needed is getting more and more. Therefore, the corresponding number of integrated circuit (IC) is raised and thus the cost is increased. This is the main disadvantage of the conventional gate line driving circuit with horizontal outputs.

Please refer to FIG. 3, which illustrates a time verses waveform chart of the signals output from the level shifters 212 of FIG. 2. As shown in FIG. 3, the output signals of the level shifters 212 transmitted through the gate lines 22 are not output at the same time. The level shifters 212 would be activated in a specific sequence. The second level shifter 2122 is activated after the first level shifter 2121 completed its work, and the third level shifter 2123 is activated after the second level shifter 2122 and so on. And, after the Nth level shifter 212N completes its work, the first level shifter 2121 would be activated again and a new activation cycle starts.

Because of the technical defects described above, the applicant keeps on carving unflaggingly to reuse the resting level shifters more efficiently. The amount of the pins needed by gate line driving circuit is reduced and the number of the relevant integrated circuits (ICs) and the cost thereof are also reduced.

Please refer to FIG. 4 and FIG. 5, which respectively illustrate a schematic view and a waveform chart of a conventional source line driving circuit of the display. As shown in FIG. 4, a conventional source line driving circuit 41 includes a source line driver control logic circuit 411, a plurality of digital-to-analog converters (DAC) 412, a plurality of output buffers 413 and a plurality of source lines 42. As the resolution of a display is getting higher and higher, the number of the source line driving circuit 41 is getting more and more. Naturally, the corresponding number of the integrated circuits (ICs) is raised and the cost of a display is increased accordingly. Therefore, the above discussion is the main disadvantage of the framework of a driving circuit with horizontal outputs.

Please refer to FIG. 5, which illustrates a waveform chart of the outputs of the driving signals of the source lines 42 of FIG. 4. As shown in FIG. 5, while the potential level of the gate line output signal Gi is raised to a high-level state, the complete horizontal waveform of the image signal is transmitted to the display by the output of the driving signals of the source line 42j and the image (source line) signals in each output column are shown at the same time. As shown in FIG. 5, the pixel elements at positions from (1,1), (1,2), (1,3), (1,4) to (1,m) are shown at the same time. And following the sequential gate line outputs, the image would be reconstructed on the display by the n times m (n*m) pixel elements.

Generally speaking, the number of source lines in vertical direction of a display is four times or more than four times of the number of scanning lines in horizontal direction. More practically, the display with a wider monitor would need more vertical source lines and naturally it would need both a more complex source line control circuit and more source line driving circuits. The conventional source line driving circuit can't solve the problem described above. Therefore, another object of the present invention is to apply a new driving method to solve this problem.

Recently, since the size of the display is getting larger, the relevant resist-capacity delay of the gate lines 22 are getting worse and the image quality, such as the flicker, is deteriorated. For this reason the third object in present invention is to solve this problem.

Summarizing the above descriptions, we conclude some disadvantages of the framework of the conventional driving circuit, which drives signals in horizontal direction, and specify them as below. First, since the number of the horizontal dots per inch (dpi) of a display is increased, the demand for the level shifters 212 is increased. Correspondingly, the chip size of gate line driver IC is larger, and the number of the relevant IC is increased. Second, since the number of vertical dots per inch (dpi) of a display is increased, the demand for the digital-to-analog converters 412 and the output buffers 413 are increased. Correspondingly, the chip size of the source line driver IC is larger, and the number of the relevant IC is increased. Third, since the size and amount of the chip of the driver IC are increased, the relevant materials and cost are increased. Finally, the problem of the flicker on the screen caused by the resistance-capacity delay of the gate line is getting more serious since the larger screen size is needed for the display.

### SUMMARY OF THE INVENTION

It is an object of the present to provide an active matrix display. The active matrix display includes a first substrate and a second substrate corresponding to the first substrate, a plurality of transistors disposed between the first substrate and the second substrate, wherein each of the plurality of transistors has a gate electrode and a source electrode electrically connected to the corresponding gate electrode, a multiplexer electrically connected to the gate electrodes, a gate line driving circuit electrically connected to the multiplexer; and a source line driving circuit electrically connected to the source electrode. The source line driving circuit generates a plurality of source line outputs and a first number of the source line outputs is defined as n. The multiplexer generates a plurality of gate line outputs and a second number of the gate line outputs is defined as m. The number n is less than the number m.

Preferably, a third number of the transistors is defined as n multiplying m.

Preferably, the multiplexer is disposed on one of the first substrate and the second substrate.

Preferably, the n is close to a quarter of m.

Preferably, the gate line driving circuit generates a multiplexer controlling signal for controlling the multiplexer.

Preferably, the gate line driving circuit generates a plurality of gate line driving signals, and a fourth number of the gate line driving signals is defined as k.

Preferably, k is less than m.

Preferably, k is an integer close to a square root of m.

Preferably, the source line driving circuit further includes a source line controlling circuit, a plurality of digital-to-analog converters electrically connected to the source line controlling circuit; and a plurality of output buffers respectively electrically connected to the digital-to-analog converters for generating the source line outputs.

Preferably, the gate line driving circuit further includes a gate line controlling circuit electrically connected to the multiplexer for generating the multiplexer controlling signal and a plurality of level shifter electrically connected to the gate line driving circuit and the multiplexer for generating the gate line driving signals.

In accordance with another aspect of the present invention, an active matrix display is provided. The active matrix display includes a first substrate and a second substrate corresponding to the first substrate, a plurality of transistors disposed between the first substrate and the second substrate, wherein each of the plurality of transistors has a gate electrode and a source electrode electrically connected to the corresponding gate electrode, a first multiplexer electrically connected to a first part of the gate electrodes, a second multiplexer electrically connected to a second part of the gate electrode, a first gate line driving circuit electrically connected to the first multiplexer, a second gate line driving circuit electrically connected to the second multiplexer and a source line driving circuit electrically connected to the source electrode. The source line driving circuit generates a plurality of source line outputs and a first number of the source line outputs is defined as n. The first and the second multiplexers generate a plurality of gate line outputs and a second number of the gate line outputs is defined as m. the first number n is less than the second number m.

Preferably, a third number of the transistors is defined as n multiplying m.

Preferably, the first multiplexer is disposed on one of the first substrate and the second substrate.

Preferably, the second multiplexer is disposed on one of the substrate and the second substrate.

Preferably, n is close to a quarter of m.

Preferably, the first gate line driving circuit generates a first multiplexer controlling signal for controlling the first multiplexer.

Preferably, the second gate line driving circuit generates a second multiplexer controlling signal for controlling the second multiplexer.

Preferably, the first and the second gate line driving circuits generate a plurality of gate line driving signals, and a fourth number of the gate line driving signals is defined as k.

Preferably, k is less than m.

Preferably, k is an integer close to a square root of m.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a structural schematic view showing an n*m active matrix display in the prior art;

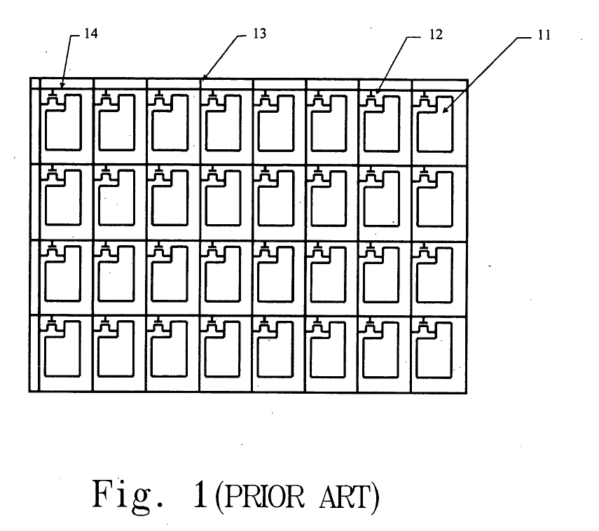

FIG. 2 is a schematic view showing a gate line driving circuit in the prior art;

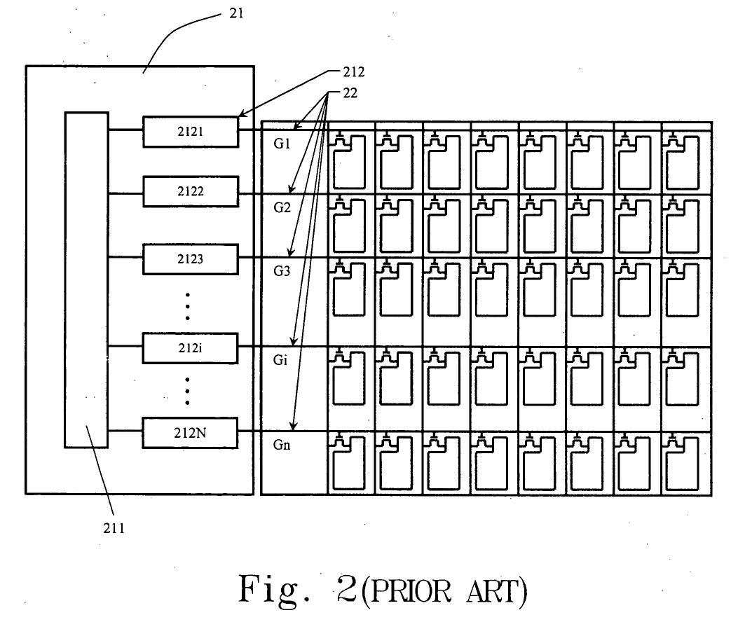

FIG. 3 is a schematic view showing the waveform chart of a output of the driving signal of the gate line in the prior art;

FIG. 4 is a schematic view showing a source line driving circuit in the prior art;

FIG. 5 is a schematic view showing the waveform chart of a output of the driving signal of the source line in the prior art;

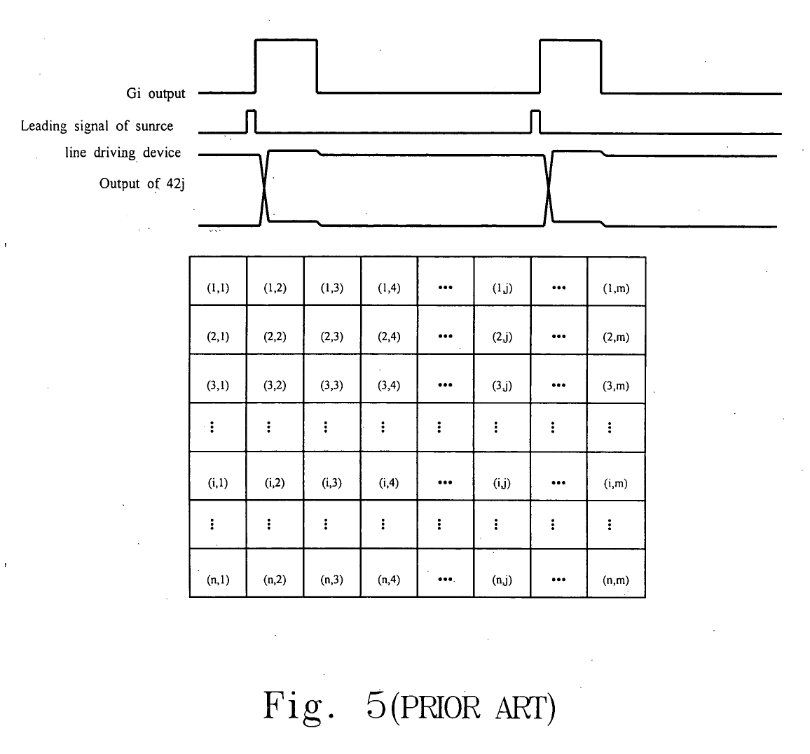

FIG. 6 is a structural schematic view showing an active matrix display according to the preferred embodiment of the present invention;

FIG. 7 is a schematic view showing a multiplexer according to the preferred embodiment of the present invention;

FIG. 8 is a schematic view showing the waveform chart of the controlling signals and the relevant input and output signals of the multiplexer according to the preferred embodiment of the present invention;

FIG. 9 is a schematic view showing the waveform chart of the output signal of the gate line driving circuit according to the preferred embodiment of the present invention;

FIG. 10 is a block diagram showing an active matrix display system according to the preferred embodiment of the present invention; and

FIG. 11 is a structural schematic view showing an active matrix display according to another preferred embodiment of the present invention.

### DETAILED DESCRIPTION OF THE PREFERRED EMBODIMENT

As described above, because of the disadvantages of the conventional gate line driving circuit, it is an object of the present invention to provide a new gate line driving circuit. The present invention, including the framework, the principle, and the applications, will now be described more specifically with reference to the following embodiments. It is to be noted that the following descriptions of preferred embodiments of this invention are presented herein for purpose of illustration and description only; it is not intended to be exhaustive or to be limited to the precise form disclosed.

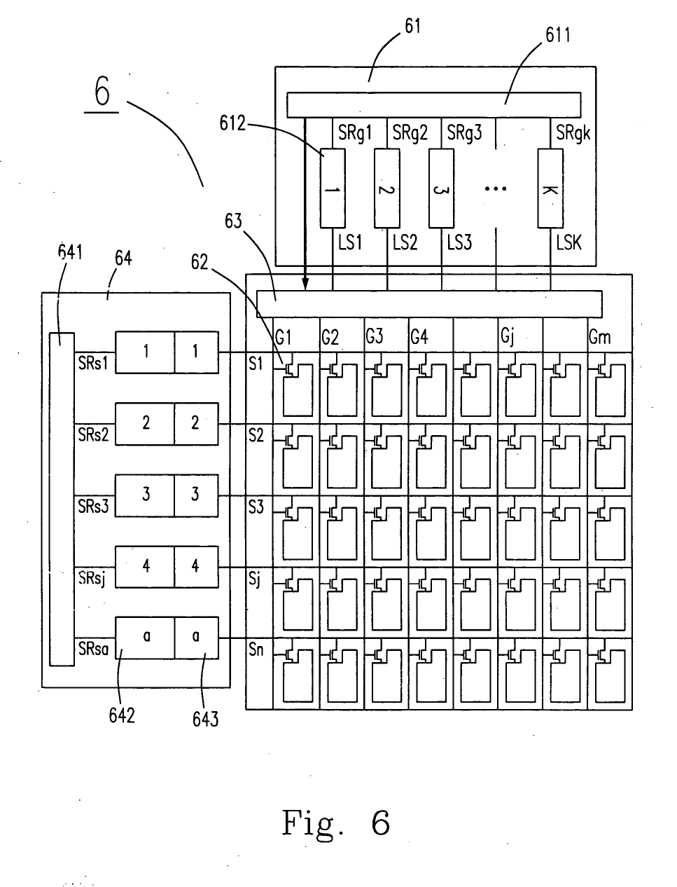

Please refer to FIG. 6, which illustrates a schematic view of an active matrix display in a first preferred embodiment according to the present invention. As shown in FIG. 6, the active matrix display 6 includes a plurality of transistors 62, a gate line driving circuit 61, a multiplexer 63, and a source line driving circuit 64.

The gate line driving circuit 61 includes a gate line controlling circuit 611 for generating a multiplexer controlling signal 160 and a plurality of potential signals (SRgl˜SRgk), and a plurality of level shifters 612 for signals.

The source line driving circuit 64 includes a source line controlling circuit 641 for generating a plurality of digital signals (SRsl), a plurality of digital-to-analog converters 642 respectively connected to the source line controlling circuit 641 to generate a plurality of analog signals in response to the digital signals, and a plurality of output buffers 643 respectively connected to the digital-to-analog converters 642 to generate the source line outputs (Sl˜Sn) in response to the analog signals.

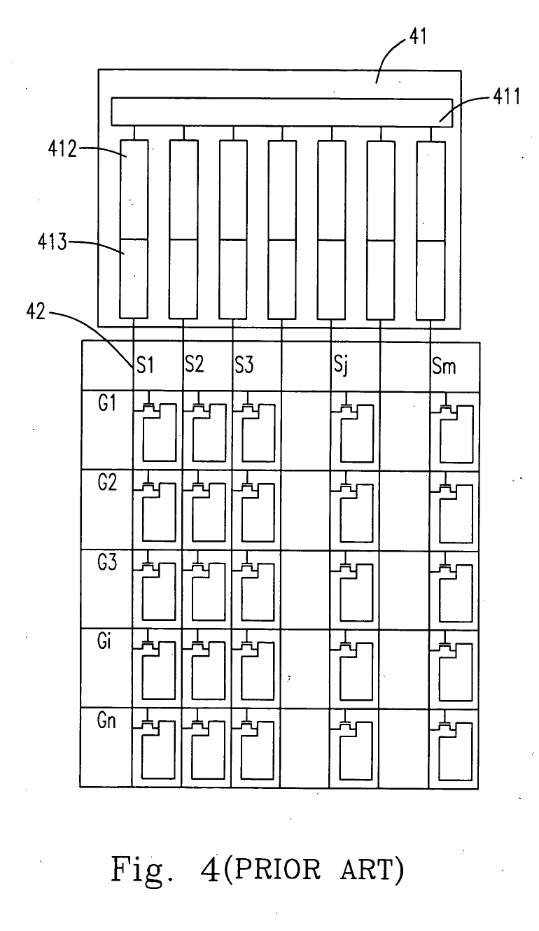

It is noted that the gate line driving circuit 61 used to drive the gate lines (Gl˜Gm) is rearranged to drive in the vertical direction, and the source line driving circuit 64 is rearranged to drive in horizontal direction. In response to that, the thin film transistors (TFT) of the display 6 are rotated 90 degree counterclockwise in respect to those in FIG. 4. Therefore, the present invention overcomes the drawbacks in the prior art in the aspects of the loading of gate lines, which is at least one fourth less than that in the prior art, the flicker problem and the image quality of a display.

The value of the dots per inch (dpi) is usually used for determining the resolution of a display. Since the dpi of a display is a fixed number n times m (n*m), simply swapping the poison of the gate line driving circuit and the source line driving circuit is not able to reduce the number of driver ICs but is able to increase the number of level shifters 612. To get over this, it is another object of the present invention to provide a new gate line driving method for the new framework of display 6.

The principle of gate line driving circuit in the present invention is based on that the gate lines scan in a specific sequence. In a picture frame, the scanning sequence is that the next column is turned on and off after the prior one is completely done and each column is only turned on and off in a short moment. In each picture frame, gate line starts its special scanning sequence, from the left to the right, one by one. To levitate the efficiency of gate line driving circuit 61, a multiplexer circuit 63 is introduced into the active matrix display 6 in the present invention. To keep the dpi of the display remains, the output number of multiplexer circuit 63 should be equal to the original sum of the gate lines, which is equal to the number m in FIG. 6. But, the input number of multiplexer circuit 63 is reduced to k, wherein the number k is less than the number m. And, the number k equals to the number of level shifters 612 of gate line driving circuit 61.

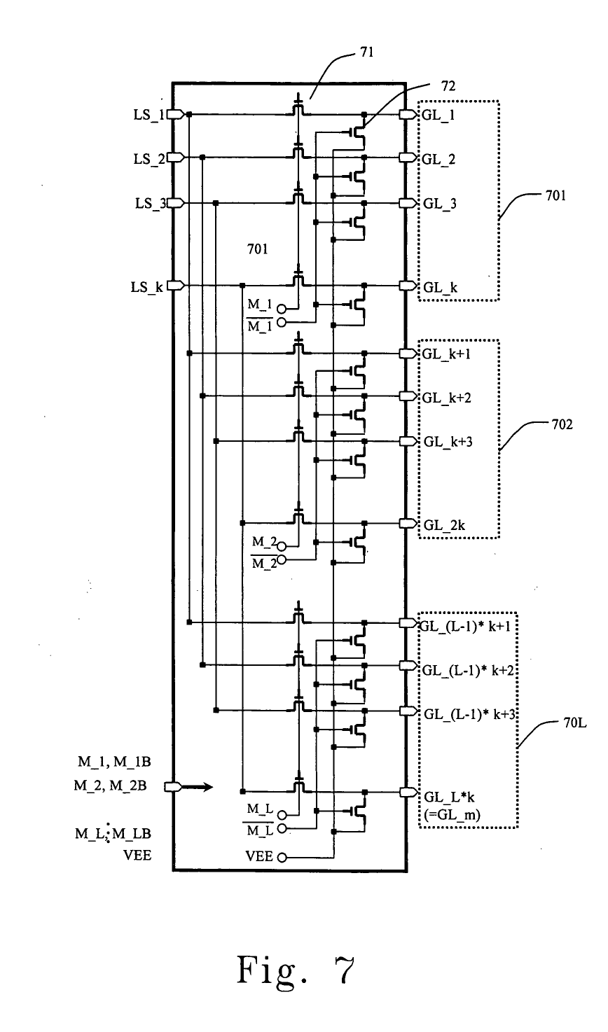

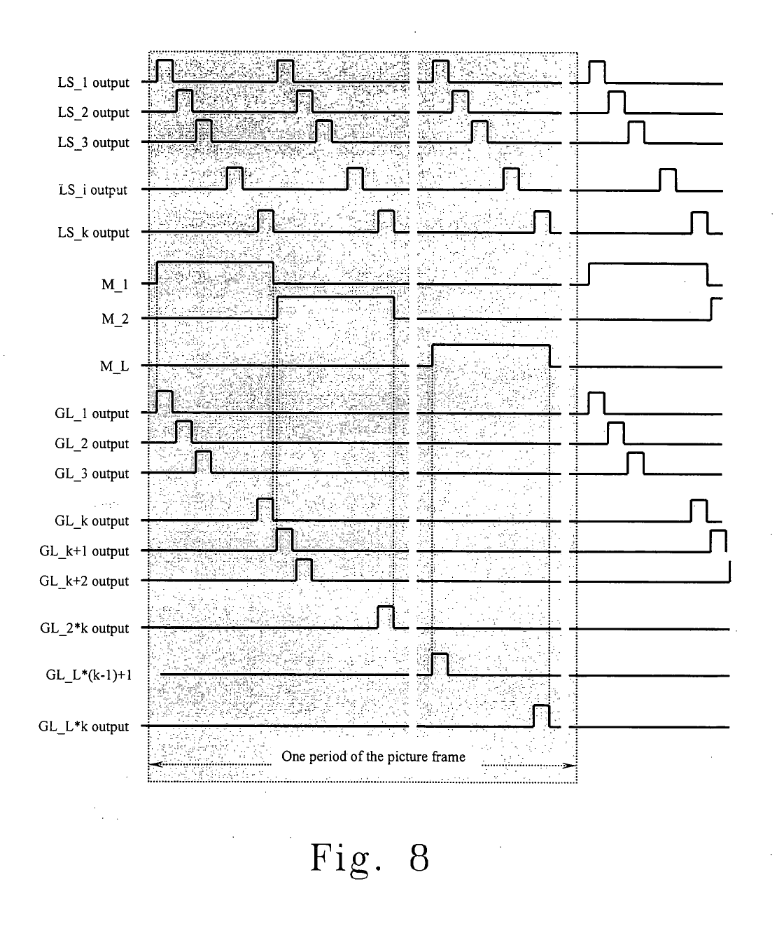

The circuit diagram and the relevant driving principle of multiplexer circuit 63 will be described in the flowing FIG. 7 and FIG. 8. The purpose of using a multiplexer circuit 63 is to reduce the number of level shifters 612 needed in the gate line driving circuit 61. This also means that the output pins of the gate line driver ICs and the relevant cost would be reduced. Moreover, the multiplexer would be able to suitably use the transistor utilized in the active matrix display. Consequently, the complexity of the process and the relevant cost of the present invention are less than those in the prior art.

In addition, there is no need to design a particular source line driver IC for the source line circuit in the present invention, and the available source line driver ICs can right be utilized. However, the image signals should be processed a 90 degrees transformation.

Please refer to FIG. 7, which is a schematic view showing a circuit diagram of the multiplexer according to the present invention. The multiplexer circuit 63 is constructed based on the transistor switch element of the active matrix display. The multiplexer circuit 63 includes a plurality of transmitting transistors 71 and a plurality of ground transistors 72, wherein a plurality of transmitting transistors 71 are electrically connected with a plurality of ground transistors 72. As shown in FIG. 7, it only needs k level shifters 612 to drive m gate lines (GL_l˜GL_m), wherein number k is less than number m. And each gate line is connected to a corresponding transmitting transistor 71 and a corresponding ground transistor 72.

The action principle of the multiplexer circuit 63 is specified as fellows. The m gate lines are divided into L groups and each group has k gate lines, wherein there are k gate line driving signals (LS_˜LS_k) output from corresponding k level shifters 612. The multiplexers M_{—}1, M_{—}2, . . . and M_L, wherein the controlling signals for multiplexers are generated by the gate line driving circuit 611, are responsible for controlling the action of the gate line group one 701, group two 702, . . . and group L 70L respectively, wherein only one gate line group outputs gate line driving signals at one time. This also means that when the gate line group one 701 outputs gate-line driving signals, the other L-1 gate line groups stay in the VEE signal states. The gate line group one 701 is switched off by the controlling signal outputs from M_{—}1, and then the gate line group two 702 driven by M_{—}2 would be activated. The rule is obeyed until the action of the gate line group L 70L is completed, and then the m gate line signals are driven, wherein the number m equals to the value of L times k. And, as the next trigger signal arrives, the action from the gate line group one 701 to the gat line group L 70L would be repeated. Finally, the image of the display is constructed by the persistent actions described above.

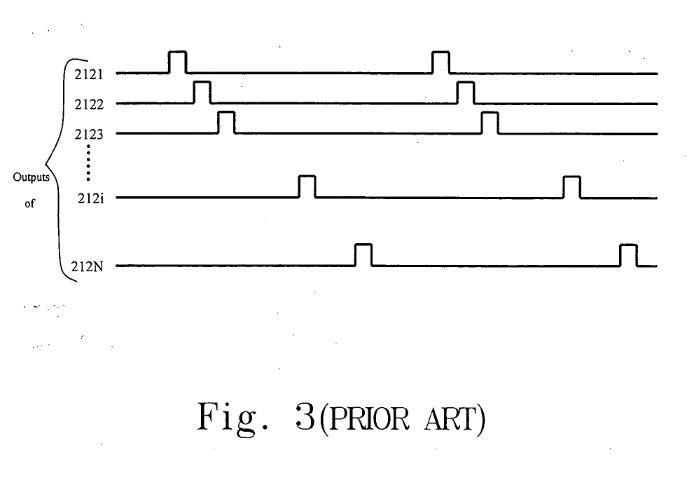

Please refer to FIG. 8, which is schematic view showing the waveform chart of the controlling signals and the relevant input and output signals of the multiplexer according to the preferred embodiment of the present invention. Comparing FIG. 8 with FIG. 3, it shows that less level shifters 612 (number k, preferably an integer close to the square root of the number m) is needed to drive more gate lines (m) in present invention. Therefore, the use of gate line driver ICs in the gate line driving circuit 61 is reduced and then the manufacturing cost is decreased. Each gate lines only needs two transistor switch elements; they are a transmitting transistor 71 and a ground transistor 72. Since there are transistor elements in the active matrix display already, no extra manufacturing process is needed and no extra cost would be added.

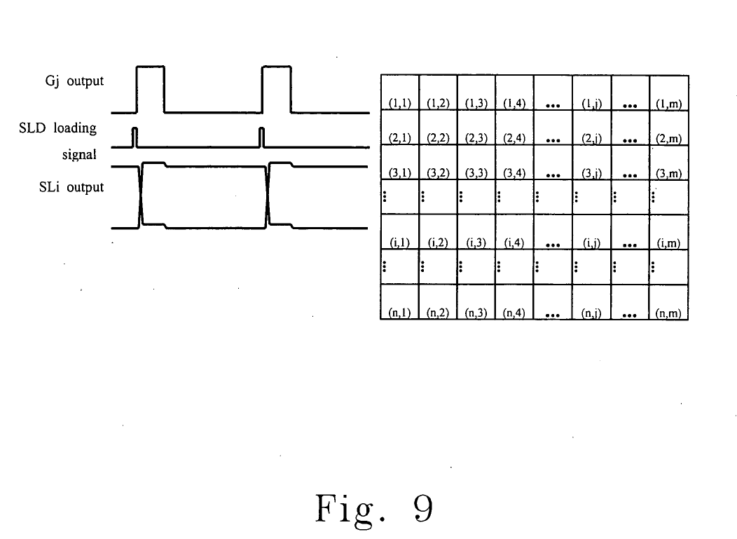

Please refer to FIG. 9, which is a schematic view showing the waveform chart of the output signal of the gate line driving circuit according to the preferred embedment of the present invention. As shown in FIG. 9, we can clearly comprehend that the outputs of source line driving circuit are changed into horizontal direction, which is different from the outputs of the vertical source lines in the prior art. The horizontal source lines transmit the image signals to the display and the image signals in each column show at the same time. As shown in FIG. 9 the pixel position (1,1), (2,1), (3,1), (4,1) to position (n, 1) would be shown at the same time. And the intact image (n*m) would be reconstructed on the display by combining the source line outputs with the sequential gat line outputs.

Certainly, because the direction of the image signals has to be rotated 90 degrees to match that of the swapped driving circuits while in use, it needs to use the frame memory to store and transform the image signals in the present invention. However, because the advancement of science and technology makes the lower price and bigger memory capacity available, only one frame memory IC is added in present invention to satisfy the dpi of present display. In view of aforesaid, the cost of added frame memory IC is far less than the cost saved from reducing the driving ICs in the present invention.

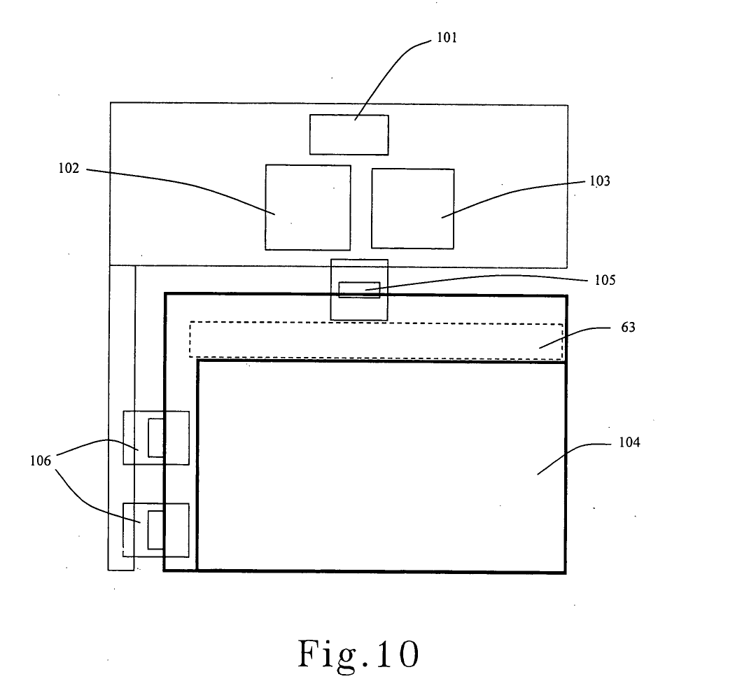

Please refer to FIG. 10, which is a block diagram showing an active matrix display system according to the present invention. The active matrix display includes a control circuit 101, a main control IC 102, a memory IC 103, a gate line driver IC 105 for generating plural gat line driving signals, a multiplexer 63, two source line driver ICs 106 for generating a plurality of source line driving signals, and an active matrix display area 104. Since, the working processes of the gate line driver IC 105, the multiplexer 63, the source line driver ICs 106 and the active matrix display area 104 are specified in the contents of FIG. 6, the relevant descriptions will not be described here.

As shown in FIG. 10, the control circuit 101 and the main control IC 102 in the system are utilized for generating the controlling signals used to control the gate driver IC 105 and the source driver ICs 106. The memory IC 103 serves as a frame memory that is used for storing and transforming the image signals and it can be integrated into the main control IC 102 or can be operated independently. In the system shown here, the driving method worked by the memory IC 103 first converting the source line driving signals to horizontal outputs and then converting the gate line driving signals to vertical outputs. Then, the image signals of source line would be transmitted to the active matrix display area 104 and combined that with the sequencing gate line output signals to reconstruct the intact images on the active matrix display area 104.

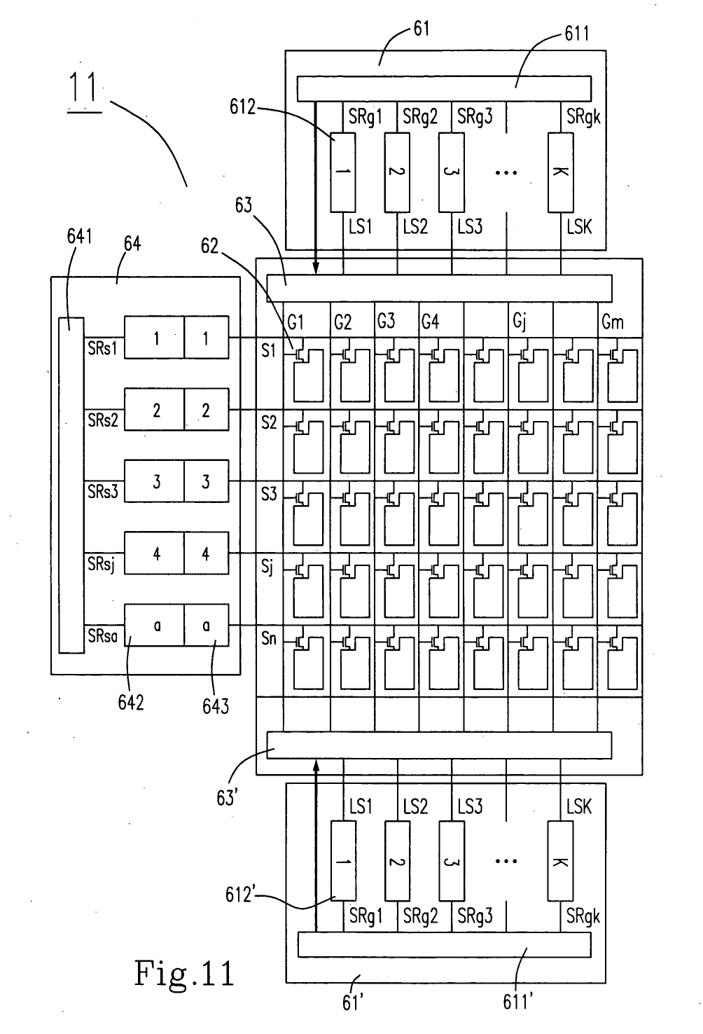

Please refer to FIG. 11, which is a structural schematic view showing an active matrix display in a second preferred embodiment according to the present invention. The active matrix display 11 includes a plurality of transistors 62, a first gate line driving circuit 61, a second gate line driving circuit 61′, a first multiplexer 63, a second multiplexer 63′ and a source line driving circuit 64.

The plurality of transistors 62 are thin film transistors. And each of the gate line driving circuit (61, 61′) includes it's own gate line controlling circuit (611, 611′) for generating a multiplexer controlling signal 160 and a plurality of gate line driving signals and it's own the plurality of level shifters (612, 612′) for generating plural gate line driving signals in response to the corresponding electrical potential signals.

The source line driving circuit 64 includes a source line controlling circuit 641 for generating a plurality of digital signals, a plurality of digital-to-analog converters 642 for generate a plurality of analog signals in response to the digital signals, and a plurality of output buffers 643 for generating the source line outputs in response to the analog signals.

The difference between FIG. 6 and FIG. 11 is that the display 11 in FIG. 11 uses two gate line driving circuits (61, 61′) and two multiplexers (63, 63′) instead the gate line driving circuits (61) and the multiplexers (63) in FIG. 6, and the other relationships are the same with FIG. 6. As shown in FIG. 11, the gate line driving circuits (61, 61′) and multiplexers (63, 63′) are respectively connected to the different side of the transistors 62. Moreover, the gate line outputs of each multiplexer (63, 63′) are connected or interconnected to parts of the gate electrodes of the transistors 62 for increasing the driving ability of the display 11. Therefore, the greater driving ability illustrated in FIG. 11 is suitable for the display with large screen and without losing its resolution. But, it should also be noted that this embodiment is only employed for illustrating and the positions and numbers of either the multiplexers or the gate line driving circuits should not be limited by these illustrated embodiments.

Further, due to the transistors are rotated 90 degrees in the present invention, the active matrix display has several features described as fellows. First, the position the of gate line driving circuit and the source line driving circuit is swapped. Second, the gate line driving signals are changed into vertical outputs and the source line driving signals are changed into horizontal outputs. Third, a memory is added for image storage and transformation.

Thus, the corresponding vale of the dpi of the gate line driving circuit is changed from m in horizontal direction to n in vertical direction. At present the number m is four times of number n or even much more than that. Namely, the flicker happened on screen would became less than one fourth of that in prior art.

The following describes that taking the dpi number of XGA as an example to compare the elements used in conventional active matrix display with the one in the present invention. First, the gate line driver ICs are reduced from three to one in the present invention, wherein the multiplexer is introduced. Second, the number of source lines driven by source line driving circuit is reduced from m to n in the present invention. Third, the source line driver ICs are reduced from eight to two in the present invention. In summary, the total number of driver ICs is reduced and one memory and 2 m transistors of multiplexer are added in the present invention. However, the transistor is an element already used in active matrix display, there is no need for a new process and the relevant cost of the new process is saved. In addition, the cost for a memory is much less than the cost saved by reducing the total number of driver ICs.

In view of the aforesaid, the active matrix display and the driving method therefor in the present invention can efficiently improve the flicker problem, increase the quality of images and decrease the number of the used driving without altering the processes. In addition, the present invention also has the advantage of reducing the manufacturing cost. Therefore, it is valuable for the industry.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims that are to be accorded with the broadest interpretation so as to encompass all such modifications and similar structures.

1. An active matrix display, comprising:
a first substrate and a second substrate corresponding to said first substrate;
a plurality of transistors disposed between said first substrate and said second substrate, wherein each of said plurality of transistors has a gate electrode and a source electrode electrically connected to said corresponding gate electrode;
a multiplexer electrically connected to said gate electrodes;
a gate line driving circuit electrically connected to said multiplexer; and
a source line driving circuit electrically connected to said source electrode, wherein said source line driving circuit generates a plurality of source line outputs, a first number of said source line outputs is defined as n, said multiplexer generates a plurality of gate line outputs, a second number of said gate line outputs is defined as m, and n is less than m.

2. The active matrix display according to claim 1, wherein a third number of said transistors is defined as n multiplying m.

3. The active matrix display according to claim 1, wherein said multiplexer is disposed on one of said first substrate and said second substrate.

4. The active matrix display according to claim 1, wherein n is close to a quarter of m.

5. The active matrix display according to claim 1, wherein said gate line driving circuit generates a multiplexer controlling signal for controlling said multiplexer.

6. The active matrix display according to claim 1, wherein said gate line driving circuit generates a plurality of gate line driving signals, and a fourth number of said gate line driving signals is defined as k.

7. The active matrix display according to claim 6, wherein k is less than m.

8. The active matrix display according to claim 6, wherein k is an integer close to a square root of m.

9. The active matrix display according to claim 1, wherein said source line driving circuit further comprises:
a source line controlling circuit;
a plurality of digital-to-analog converters electrically connected to said source line controlling circuit; and
a plurality of output buffers respectively electrically connecting to said digital-to-analog converters for generating said source line outputs.

10. The active matrix display according to claim 1, wherein said gate line driving circuit further comprises:
a gate line controlling circuit electrically connected to said multiplexer for generating said multiplexer controlling signal; and
a plurality of level shifter electrically connected to said gate line driving circuit and said multiplexer for generating said gate line driving signals.

11. An active matrix display, comprising:
a first substrate and a second substrate corresponding to said first substrate;
a plurality of transistors disposed between said first substrate and said second substrate, wherein each of said plurality of transistors has a gate electrode and a source electrode electrically connected to said corresponding gate electrode;
a first multiplexer electrically connected to a first part of said gate electrodes;
a second multiplexer electrically connected to a second part of said gate electrode;
a first gate line driving circuit electrically connected to said first multiplexer;
a second gate line driving circuit electrically connected to said second multiplexer; and
a source line driving circuit electrically connected to said source electrode;
wherein said source line driving circuit generates a plurality of source line outputs, and a first number of said source line outputs is defined as n, said first and said second multiplexers generate a plurality of gate line outputs, a second number of said gate line outputs is defined as m, and n is less than m.

12. The active matrix display according to claim 11, wherein a third number of said transistors is defined as n multiplying m.

13. The active matrix display according to claim 11, wherein said first multiplexer is disposed on one of said first substrate and said second substrate.

14. The active matrix display according to claim 11, wherein said second multiplexer is disposed on one of said substrate and said second substrate.

15. The active matrix display according to claim 11, wherein n is close to a quarter of m.

16. The active matrix display according to claim 11, wherein said first gate line driving circuit generates a first multiplexer controlling signal for controlling said first multiplexer.

17. The active matrix display according to claim 11, wherein said second gate line driving circuit generates a second multiplexer controlling signal for controlling said second multiplexer.

18. The active matrix display according to claim 11, wherein said first and said second gate line driving circuits generate a plurality of gate line driving signals, and a fourth number of said gate line driving signals is defined as k.

19. The active matrix display according to claim 18, wherein k is less than m.

20. The active matrix display according to claim 18, wherein k is an integer close to a square root of m.
